(19) United States
(12) Patent Application Publication
(10) Pub. No.: US 2007/0072132 A1
(43) Pub. Date: Mar. 29, 2007

(54) Method of forming device structure, method of manufacturing magnetoresistive element, and method of manufacturing thin film magnetic head

(75) Inventors: Akifumi Kamijima, Tokyo (JP); Hitoshi Hatate, Tokyo (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 11/523,591

(22) Filed: Sep. 20, 2006

(30) Foreign Application Priority Data
Sep. 27, 2005 (JP) 2005-280389

(51) Int. Cl. G03F 7/26

(52) U.S. Cl. 430/314; 430/311; 430/313

(57) ABSTRACT

The present invention provides a method of forming a device structure realizing a narrowed pattern width without using a lift off method. A first device layer is selectively etched through using a photoresist pattern, thereby forming a first device layer pattern. After that, a second device layer is formed so as to cover the first device layer pattern, the photoresist pattern, and a substrate around the first device layer pattern and the photoresist pattern, and the second device layer covering a side wall of the photoresist pattern is selectively removed through oblique etching process, thereby forming a second device layer pattern. The first device layer pattern is formed so as to have a very small pattern width through the etching in place of the lift off method, and the second device layer pattern is filled in the space around the first device layer pattern.

### BACKGROUND OF THE INVENTION

1. Field of the Invention

The present invention relates to a method of forming a device structure for forming a device structure such as a magnetoresistive element, a method of manufacturing a magnetoresistive element, and a method of manufacturing a thin film magnetic head having a magnetoresistive element.

2. Description of the Related Art

In recent years, a magnetic recording apparatus for executing magnetic reading process utilizing a magnetic recording medium is being spread. In the development field of the magnetic recording apparatus, as the surface recording density of a magnetic recording medium improves, improvement in the performance of a thin film magnetic head is in demand. The thin film magnetic head has, as a device structure for reading process, a magneto-resistive (MR) element for executing reading process through using the magneto-resistive (MR) effect.

Generally, an MR element having excellent reading performance has a stack structure called a spin valve structure. On the basis of the kind of the magneto-resistive effect, MR elements of this kind are classified into GMR elements utilizing giant magneto-resistive (GMR) effect and MTJ elements utilizing magnetic tunnel junction (MTJ) effect (tunnel magnetoresistive (TMR) element). On the basis of the flowing direction of the sense current, the GMR elements are further classified into current-in-the-plane (CIP) GMR elements in which sense current flows in the direction parallel with the plane and current-perpendicular-to-the-plane (CPP) GMR elements in which sense current flows in the direction orthogonal to the plane.

A CPP-GMR element typified by the series of MR elements is generally manufactured by the following procedure. Specifically, first, an MR layer is formed so as to have a stack structure including a pinning layer, a pinned layer, a spacer layer, and a free layer on a bottom shield layer. After that, a photoresist pattern for lift-off (so-called bi-layer resist pattern) is formed on the MR layer so as to have an undercut. Subsequently, the MR layer is selectively etched using the photoresist pattern as a mask to form an MR layer pattern. An insulating layer (gap layer) and a magnetic bias layer are stacked in this order so as to cover the MR layer pattern, the photoresist pattern, and a bottom shield layer around the MR layer pattern and the photoresist pattern. Finally, through lifting off the photoresist pattern, a gap layer pattern and a magnetic bias layer pattern are stacked so as to be filled in spaces on both sides in the read track width direction of the MR layer pattern. As a result, the CPP-GMR element is completed.

The CIP-GMR element is manufactured through a procedure similar to the above-described CPP-GMR element manufacturing procedure except for the point that a magnetic bias layer pattern and a lead layer pattern are formed in place of the gap layer pattern and the magnetic bias layer pattern, respectively. The MTJ element is manufactured through a procedure similar to the above-described CPP-GMR element manufacturing procedure except for the point that an MR layer pattern is formed so as to have a stack structure including a tunnel barrier layer in place of the spacer layer.

With respect to the method of manufacturing the MR element, some manufacturing procedures other than the above-descried manufacturing procedures have been proposed. Concretely, as a method of manufacturing the CPP-GMR element and the MTJ element, there is a known manufacturing method in which an insulating layer, a magnetic bias layer, and an insulating layer are stacked in this order so as to bury an MR layer pattern and a photoresist pattern. Subsequently, the whole is planarized by being polished until the photoresist pattern is exposed through using chemical mechanical polishing (CMP) or etch back. After that, the used photoresist pattern is removed (refer to, for example, Japanese Patent Laid-open No. 2004-342154). There is also a known manufacturing procedure in which a photoresist pattern is formed on an MR layer. Through slimming the photoresist pattern, the width is reduced. After that, with the slimmed photoresist pattern, the MR layer is selectively etched (refer to, for example, Japanese Patent Laid-open No. 2002-323775).

### SUMMARY OF THE INVENTION

In consideration of the recent technical trend that the read track width is being narrowed, to narrow the pattern width of the MR layer pattern, while narrowing the photoresist pattern for lift-off, the photoresist pattern has to be smoothly lifted off. In the conventional method of manufacturing the MR element, however, in the case of using a bi-layer resist pattern having an undercut as the photoresist pattern, when the photoresist pattern is narrowed, the undercut is also similarly narrowed. Consequently, there is a problem such that the photoresist pattern is not easily lifted off. It is, therefore, considered that the conventional method of manufacturing the MR element using the lift off method has already reached the limit of reducing the read track width, and a novel method of manufacturing the MR element which does not use the lift off method is in demand. With respect to this point, in particular, it is important to place importance on the technical demand of reducing the pattern width and establish a method of forming not only an MR element but broadly a device structure.

In view of the drawbacks, it is desirable to provide a method of forming a device structure capable of reducing pattern width without using the lift off method.

It is also desirable to provide a method of manufacturing a magnetoresistive element and a method of manufacturing a thin film magnetic head, which can address reduction in read track width without using the lift off method.

According to an embodiment of the present invention, there is provided a method of forming a device structure including: a first step of forming a first device layer so as to cover a substrate; a second step of forming a photoresist pattern on the first device layer; a third step of forming a first device layer pattern through selectively etching the first device layer using the photoresist pattern as a mask; a fourth step of forming a second device layer so as to cover the first device layer pattern, the photoresist pattern, and the substrate around the first device layer pattern and the photoresist pattern; a fifth step of selectively removing the second device layer covering a side wall of the photoresist pattern through oblique etching process, thereby forming a second device layer pattern so as to be filled in space around the first device layer pattern; and a sixth step of removing the remaining photoresist pattern.

In the method of forming the device structure according to an embodiment of the invention, a first device layer is selectively etched through using a photoresist pattern, thereby forming a first device layer pattern. After that, a second device layer is formed so as to cover the first device layer pattern, the photoresist pattern, and a substrate around the first device layer pattern and the photoresist pattern, and the second device layer covering a side wall of the photoresist pattern is selectively removed through oblique etching process, thereby forming a second device layer pattern. In this case, the first device layer pattern is formed so as to have a very small pattern width through using the etching in place of the lift off method, and the second device layer pattern is filled in the space around the first device layer pattern. The first device layer pattern (or the first device layer) and the second device layer pattern (or the second device layer) may have a single layer configuration or a stack layer configuration. The first and second device layer patterns will be concretely described through an application example of the device structure. In the case of applying the device structure to a magneto-resistive element which will be described later, the first device layer pattern is an MR layer pattern, and the second device layer pattern is a stack body of an insulating layer pattern and a magnetic bias layer pattern, or a stack body of the magnetic bias layer pattern and a lead layer pattern.

A method of manufacturing a magnetoresistive element according to the invention includes: a first step of forming a magnetoresistive layer so as to cover a substrate; a second step of forming a photoresist pattern on the magnetoresistive layer; a third step of forming a magnetoresistive layer pattern through selectively etching the magnetoresistive layer using the photoresist pattern as a mask; a fourth step of forming a deposition layer so as to cover the magnetoresistive layer pattern, the photoresist pattern, and the substrate around the magnetoresistive layer pattern and the photoresist pattern; a fifth step of selectively removing the deposition layer covering the side wall of the photoresist pattern through oblique etching process, thereby forming a deposition layer pattern so as to be filled in spaces on both sides in a read track width direction of the magnetoresistive layer pattern; and a sixth step of removing the remaining photoresist pattern.

In the method of manufacturing the magnetoresistive element according to an embodiment of the invention, a magnetoresistive layer pattern is formed through selectively etching a magnetoresistive layer using a photoresist pattern. After that, a deposition layer is formed so as to cover the magnetoresistive layer pattern, the photoresist pattern, and a substrate around the magnetoresistive layer pattern and the photoresist pattern. The deposition layer covering a side wall of the photoresist pattern is selectively removed through oblique etching process, thereby forming a deposition layer pattern. In this case, through using the etching in place of the lift off method, the magnetoresistive layer pattern is formed so as to have a very narrow pattern width and the deposition layer pattern is filled in the spaces on both sides in the read track width direction of the magnetoresistive layer pattern.

According to an embodiment of the present invention, there is provided a method of manufacturing a thin film magnetic head having a magnetoresistive element, which manufactures a magnetoresistive element through using the above-described method of manufacturing the magnetoresistive element.

In the method of manufacturing the thin film magnetic head according to an embodiment of the invention, a magnetoresistive element is manufactured through using the above-described method of manufacturing the magnetoresistive element.

In the method of forming the device structure according to an embodiment of the invention, preferably, in the fifth step, ion milling is performed, where an ion beam is emitted from a direction at an angle in the range from 60° to 80° from a perpendicular of the substrate. In this case, the second device layer covering the side wall may be over-etched. In particular, preferably, in the fourth step, the second device layer is formed so as to be thicker than the first device layer pattern, and in the fifth step, the second device layer is etched so that the thickness of the second device layer pattern becomes equal to the thickness of the first device layer pattern.

In the method of manufacturing the magnetoresistive element according to an embodiment of the present invention, in the fourth step, a current-perpendicular-to-the-plane giant magnetoresistive element or a magnetic tunnel junction (MTJ) element may be manufactured through stacking an insulating layer and a magnetic bias layer in this order as the deposition layer, or a current-in-the-plane giant magnetoresistive element may be manufactured through stacking a magnetic bias layer and a lead layer in this order as the deposition layer in the fourth step. In this case, in the first step, the magnetoresistive layer is formed so as to have a stack structure including a pinning layer, a pinned layer, and a free layer.

The definition of the series of words is as follows. First, “substrate” is an under layer for forming the first device layer (or the magnetoresistive layer) and may be any of various substrates or various layers provided for various substrates. Second, “perpendicular of the substrate” is an imaginary line orthogonal to the surface of the substrate. Third, “the thickness of the second device layer pattern becomes equal to the thickness of the first device layer pattern” includes not only the case where both of the thicknesses strictly coincide with each other but also the case where the thicknesses are slightly different from each other although the etching is performed with intention to make both of the thicknesses coincide with each other. Fourth, “both sides in the read track width direction” denote one side and the other side in the read track width direction, specifically, one side and the other side in the arrangement direction of two deposition layer patterns.

In the a method of forming the device structure according to an embodiment of the invention, a first device layer is selectively etched through using a photoresist pattern, thereby forming a first device layer pattern. After that, a second device layer is formed so as to cover the first device layer pattern, the photoresist pattern, and a substrate around the first device layer pattern and the photoresist pattern, and the second device layer covering a side wall of the photoresist pattern is selectively removed through oblique etching process, thereby forming a second device layer pattern. Thus, the narrowed pattern width can be realized without using the lift off method.

In the method of manufacturing the magnetoresistive element or the method of manufacturing the thin film magnetic head according to an embodiment of the invention, a magnetoresistive layer pattern is formed through selectively etching a magnetoresistive layer through a photoresist pattern. After that, a deposition layer is formed so as to cover the magnetoresistive layer pattern, the photoresist pattern, and a substrate around the magnetoresistive layer pattern and the photoresist pattern. The deposition layer covering a side wall of the photoresist pattern is selectively removed through oblique etching process, thereby forming a deposition layer pattern. Thus, the invention can address reduction in the read track width without using the lift off method.

Other and further objects, features and advantages of the invention will appear more fully from the following description.

### BRIEF DESCRIPTION OF THE DRAWINGS

FIG. 1 is a cross section showing a configuration of a device structure formed through using a method of forming a device structure according to an embodiment of the invention.

FIG. 2 is a cross section showing a step in the method of forming the device structure according to the embodiment of the invention.

FIG. 3 is a cross section illustrating a step subsequent to FIG. 2.

FIG. 4 is a cross section illustrating a step subsequent to FIG. 3.

FIG. 5 is a cross section illustrating a step subsequent to FIG. 4.

FIG. 6 is an exploded perspective view showing a configuration of a thin film magnetic head manufactured through using a method of manufacturing a thin film magnetic head of the invention.

FIG. 7 is a plan view showing the configuration of the thin film magnetic head viewed from the direction of the arrow VII illustrated in FIG. 6.

FIG. 8 is a cross section showing the configuration of the thin film magnetic head in the direction of the arrow taken along line VIII-VIII illustrated in FIG. 7.

FIG. 9 is a cross section showing the configuration of a CPP-GMR element in the direction of the arrow taken along line IX-IX illustrated in FIGS. 6 and 7.

FIG. 10 is an enlarged cross section of a main part of the CPP-GMR element illustrated in FIG. 9.

FIG. 11 is a cross section illustrating a process in a method of manufacturing a CPP-GMR element.

FIG. 12 is a cross section illustrating a step subsequent to FIG. 11.

FIG. 13 is a cross section illustrating a step subsequent to FIG. 12.

FIG. 14 is a cross section illustrating a step subsequent to FIG. 13.

FIG. 15 is a cross section illustrating a step in a method of manufacturing a thin film magnetic head as a comparative example of the method of manufacturing the thin film magnetic head of the present invention.

FIG. 16 is a cross section illustrating a step subsequent to FIG. 15.

FIG. 17 is a cross section illustrating a step subsequent to FIG. 16.

FIG. 18 is a cross section showing a modification of the configuration of the thin film magnetic head.

FIG. 19 is a cross section showing another modification of the configuration of the thin film magnetic head.

FIG. 20 is a cross section illustrating a method of manufacturing a CIP-GMR element shown in FIG. 19.

### DETAILED DESCRIPTION OF THE PREFERRED EMBODIMENTS OF THE INVENTION

Embodiments of the present invention will be described in detail hereinbelow by referring to the drawings.

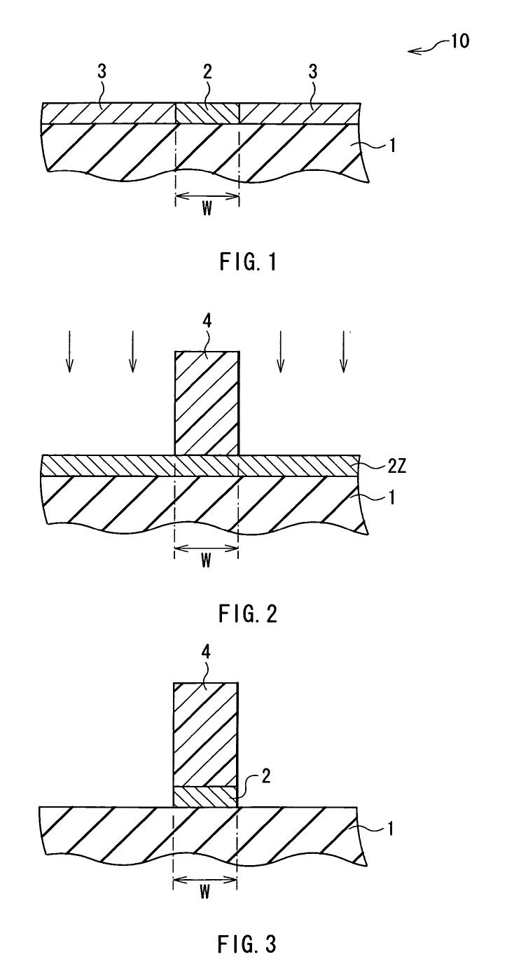

First, by referring to FIG. 1, the configuration of a device structure formed through using a method of forming a device structure according to an embodiment of the present invention will be described briefly. FIG. 1 shows a sectional configuration of a device structure 10.

The device structure 10 is applied to devices for various applications and, as shown in FIG. 1, is provided on a substrate 1. The device structure 10 has a first device layer pattern 2 and a second device layer pattern 3 buried in the space around the first device layer pattern 2.

The substrate 1 supports the device structure 10. For example, the substrate 1 may be any of various kinds of substrates and may be any of various kinds of substrates provided with various layers.

The first device layer pattern 2 is a functional layer having a predetermined function and has a very small pattern width W (for example, W=about 10 nm to 100 nm). The material, configuration (single layer configuration or stacked layer configuration), pattern shape (plane shape), dimensions (for example, thickness), and the like of the first device layer pattern 2 can be freely set in accordance with the function, application, and the like of a device to which the device structure 10 is applied.

The second device layer pattern 3 is a functional layer having a function different from that of the first device layer pattern 2, and is disposed around the first device layer pattern 2. In a manner similar to the first device layer pattern 2, the material, configuration, pattern shape, and dimensions of the second device layer pattern 3 can be freely set. In particular, the second device layer pattern 3 may be disposed, for example, entirely or partially around the first device layer pattern 2.

Next, as the method of forming the device structure according to the embodiment, a method of forming the device structure 10 shown in FIG. 1 will be described by referring to FIGS. 2 to 5. FIGS. 2 to 5 are provided for explaining process of forming the device structure 10 and correspond to the sectional configuration of FIG. 1. Since the materials, configurations, pattern shapes, dimensions, and the like of a series of elements forming the device structure 10 can be freely set as described above, their description will not be given below.

At the time of forming the device structure 10, the substrate 1 is prepared and, after that, a first device layer 2Z is formed so as to cover the substrate 1 as shown in FIG. 2. The first device layer 2Z is a preparation layer which is selectively etched in a post process, thereby becoming the first device layer pattern 2 (refer to FIG. 3).

Subsequently, a photoresist film is formed through applying the surface of the first device layer 2Z with photoresist. After that, the photoresist film is patterned (exposed and developed) through using the photolithography, thereby forming a photoresist pattern 4 on the first device layer 2Z as shown in FIG. 2. The photoresist pattern 4 is formed so as to have a pattern shape (pattern width W) corresponding to the pattern shape of the first device layer pattern 2 formed in a post process. In this case, for example, the pattern width W may be reduced through, after the photoresist pattern 4 is formed, sliming the photoresist pattern 4 through exposing the photoresist pattern 4 to oxygen plasma or the like. The resist structure of the photoresist pattern 4 may be, for example, a single-layer resist structure or a two-layer resist structure (so-called bi-layer resist pattern) having an undercut. The material of the photoresist pattern 4 (the kind of the photoresist) can be freely selected.

After that, the first device layer 2Z is selectively etched (so-called patterning) through using the photoresist pattern 4 as a mask to form the first device layer pattern 2 so as to have the pattern width W, as shown in FIG. 3. At the time of forming the first device layer pattern 2, for example, ion milling, reactive ion etching (RIE), or the like is used.

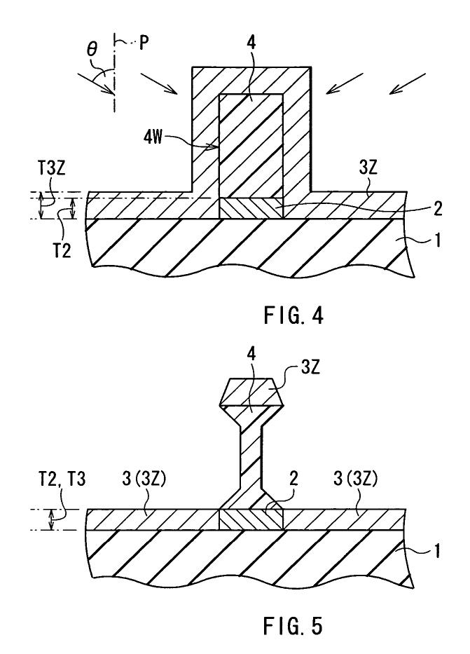

As shown in FIG. 4, a second device layer 3Z is formed so as to cover the first device layer pattern 2, the photoresist pattern 4, and the substrate 1 around the first device layer pattern 2 and the photoresist pattern 4. The second device layer 3Z is a preparation layer which becomes the second device layer pattern 3 (refer to FIG. 5) through being selectively etched in a post process. In this case, for example, thickness T3Z of the second device layer 3Z is set to be larger than thickness T2 of the first device layer pattern 2 (T3Z>T2). With the second device layer 3Z, a side wall 4W of the photoresist pattern 4 is covered.

As shown in FIG. 4, the second device layer 3Z covering the side wall 4W of the photoresist pattern 4 is selectively removed through oblique etching process. The “oblique etching process” is different from normal etching that performs etching action so that the second device layer 3Z becomes parallel with a perpendicular P of the substrate 1 (imaginary line which is orthogonal to the surface of the substrate 1) but is directional etching that produces etching action from a direction at a predetermined angle from the perpendicular P. At the time of obliquely etching the second device layer 3Z, for example, an ion beam is emitted from a direction at an angle θ of about 60° or larger, preferably, about 60° to 80° from the perpendicular P through using ion milling. In this case, for example, the second device layer 3Z covering the side wall 4W of the photoresist pattern 4 is over-etched.

Through the oblique etching process, as shown in FIG. 5, the second device layer pattern 3 is formed so as to bury the space around the first device layer pattern 2. When the second device layer 3Z is obliquely etched, through the etching action from the direction at the angle θ in the above-described range, the etching rate of a lateral etching component is higher than that of a downward etching component. Consequently, the portion covering the side wall 4W of the photoresist pattern 4 in the second device layer 3Z becomes susceptible to etching, so that the portion is etched and removed completely. On the other hand, the portion buried in the space around the first device layer pattern 2 becomes less prone to be etched, so that the portion is slightly etched but remains. In this case, for example, through over-etching the second device layer 3Z, etching is continued until the photoresist pattern 4 is partially narrowed in a center portion in a state where the first device layer pattern 2 is continuously covered with the photoresist pattern 4. In particular, at the time of obliquely etching the second device layer 3Z, for example, it is preferable to make the thickness T3 of the second device layer pattern 3 equal to the thickness T2 of the first device layer pattern 2 (T3=T2). The expression that “the thickness T3 of the second device layer pattern 3 becomes equal to the thickness T2 of the first device layer pattern 2” includes not only the case where both of the thicknesses strictly coincide with each other but also the case where the thicknesses are slightly different from each other as long as etching is performed to make the thicknesses coincide with each other. After formation of the second device layer pattern 3 (after completion of the oblique etching process), for example, the unnecessary second device layer 3Z remains on the photoresist pattern 4.

Finally, through removing the unnecessary second device layer 3Z remaining on the photoresist pattern 4 together with the remaining photoresist pattern 4, the device structure 10 is completed.

In the method of forming the device structure according to the embodiment, the first device layer pattern 2 is formed through selectively etching the first device layer 2Z through using the photoresist pattern 4 having the very small pattern width W. After that, the second device layer 3Z is formed so as to cover the first device layer pattern 2, the photoresist pattern 4, and the substrate 1 around the first device layer pattern 2 and the photoresist pattern 4. Through selectively removing the second device layer 3Z covering the side wall 4W of the photoresist pattern 4 through oblique etching process, the second device layer pattern 3 is formed. In this case, the first device layer pattern 2 is formed so as to have the very small pattern width W through using etching in place of using the lift off method, and the second device layer pattern 3 is buried in the space around the first device layer pattern 2. Therefore, the pattern width W can be narrowed without using the lift off method.

In particular, in the embodiment, as described by referring to FIGS. 4 and 5, the second device layer 3Z is etched so that the thickness T3 of the second device layer pattern 3 becomes equal to the thickness T2 of the first device layer pattern 2. Consequently, as shown in FIG. 1, the surfaces of the first and second device layer patterns 2 and 3 in the completed device structure 10 can be planarized. In this case, an advantage is obtained such that other functional layers can be formed so as to be plane on the first and second device layer patterns 2 and 3 in a post process.

The method of forming the device structure according to the embodiment of the invention has been described above.

Next, an example of applying the method of forming the device structure will be described. In the following, a method of manufacturing a thin film magnetic head having a magnetoresistive element (MR element) will be described.

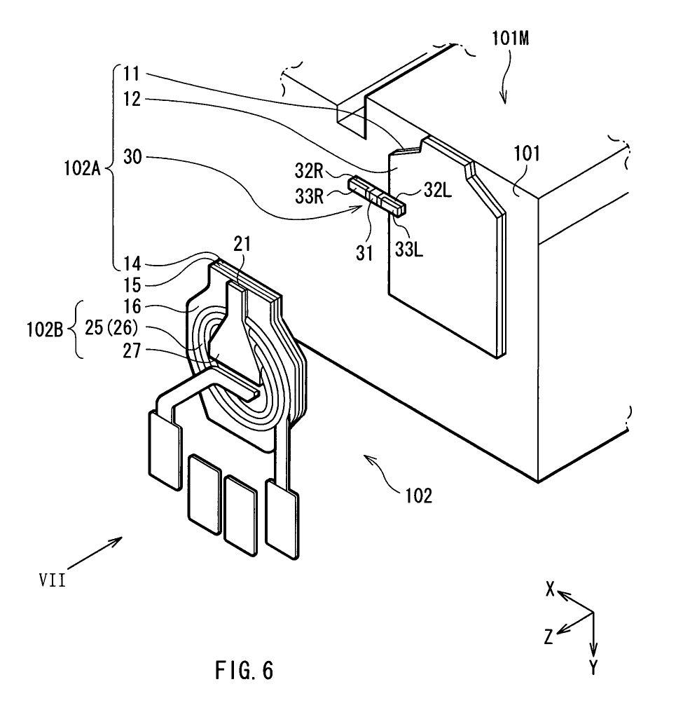

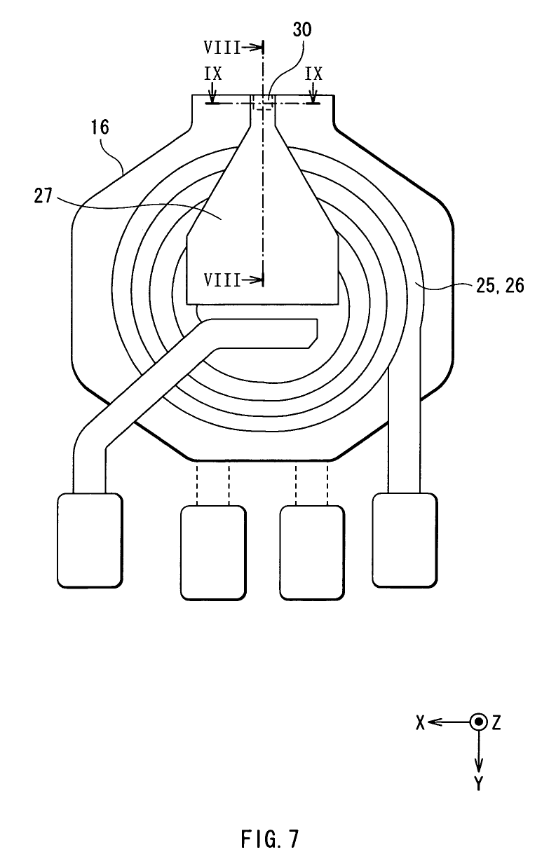

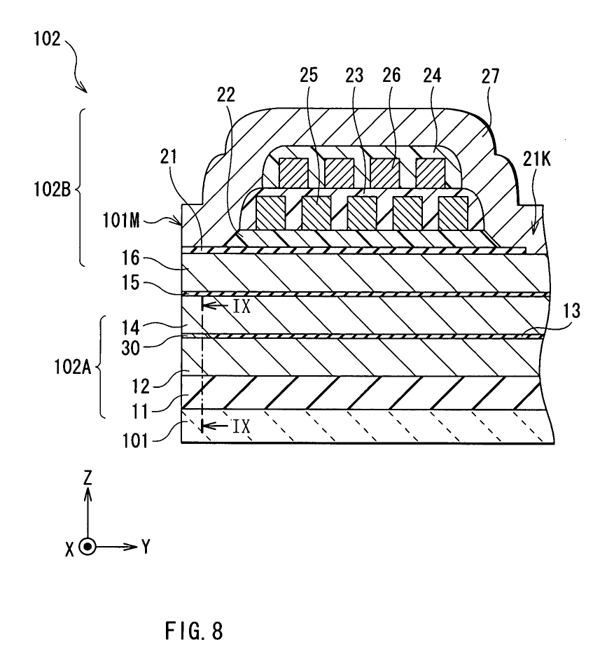

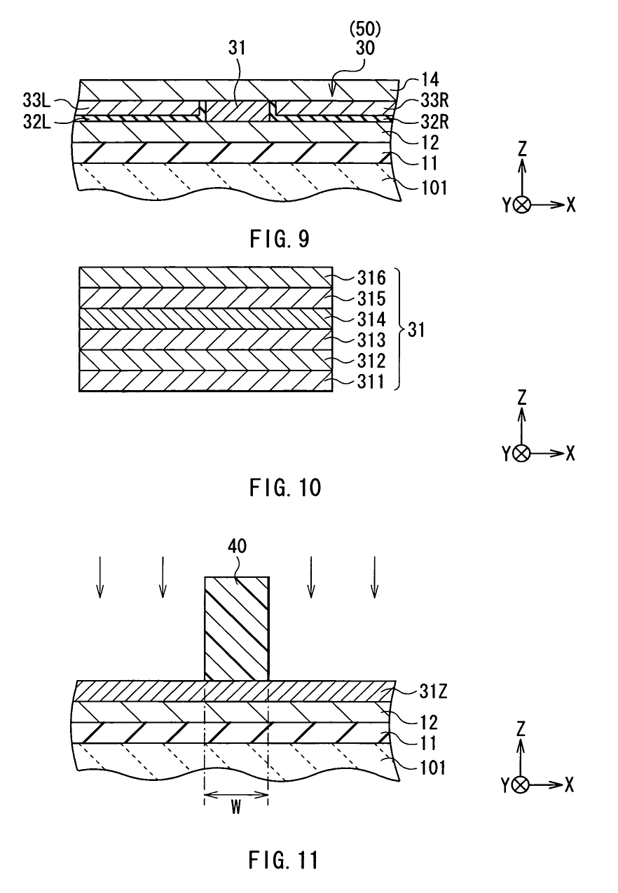

First, by referring to FIGS. 6 to 10, the configuration of a thin film magnetic head manufactured through using the method of manufacturing the thin film magnetic head will be briefly described. FIGS. 6 to 8 show the configuration of a thin film magnetic head 102. FIG. 6 is an exploded perspective view of the configuration. FIG. 7 is a plan view of the configuration viewed from the arrow VII of FIG. 6. FIG. 8 shows a sectional configuration taken along line VIII-VIII of FIG. 7. FIGS. 9 and 10 show the configuration of a main part (CPP-GMR element 30) in the thin film magnetic head 102. FIG. 9 is a schematic cross section taken along line IX-IX of FIGS. 7 and 8 of the configuration (sectional configuration parallel with an air bearing surface 101M). FIG. 10 shows an enlarged sectional configuration of a main part (MR layer pattern 31) illustrated in FIG. 9. At the time of describing the configuration of the thin film magnetic head, FIG. 1 which has been referred to for describing the device structure will be properly referred to.

As shown in FIGS. 6 to 8, the thin film magnetic head 102 is provided in one face of a slider 101 made of ceramic (such as altic (Al₂O₃.TiC)) or silicon. The air bearing surface 101M is formed through the thin film magnetic head 102 and the slider 101. The thin film magnetic head 102 is a composite head including, for example, a read head core 102A for performing reading process and a write head core 102B for performing writing process.

For example, the read head core 102A is provided on the slider 101 and has a stack structure in which an insulating layer 11, a bottom shield layer 12, the CPP-GMR element 30, an insulating layer 13, and a top shield layer 14 are stacked in this order.

The insulating layer 11 electrically isolates the read head core 102A from the slider 101 and is made of an insulating material such as an aluminum oxide (Al₂O₃, hereinbelow, called “alumina”) or silicon oxide (SiO₂). The bottom shield layer 12 and the top shield layer 14 are provided to magnetically shield the CPP-GMR element 30 from the periphery. For example, the bottom shield layer 12 and the top shield layer 14 are made of a magnetic material such as a nickel iron alloy (NiFe, hereinbelow, called “permalloy (trade name)”), iron cobalt nickel alloy (FeCoNi), or iron cobalt alloy (FeCo). The CPP-GMR element 30 magnetically reads information recorded on a magnetic recording medium (not shown) through detecting a signal magnetic field of the magnetic recording medium through using giant magnetoresistance. The detailed configuration of the CPP-GMR element 30 will be described later (refer to FIGS. 9 and 10). The insulating layer 13 is provided to electrically isolate the CPP-GMR element 30 from the periphery and is made of, for example, an insulating material such as alumina. In FIG. 6, the insulating layer 13 is not shown.

The write head core 102B is provided, for example, over the read head core 102A with a nonmagnetic layer 15 in between as shown in FIG. 8. The write head core 102B is a longitudinal write head having a stack structure in which a bottom magnetic pole 16, a write gap layer 21, thin film coils 25 and 26 constructed in two stages and buried by insulating layers 22, 23, and 24, and a top magnetic pole 27 are stacked in this order. The nonmagnetic layer 15 provides magnetic isolation between the read head core 102A and the write head core 102B and is made of, for example, alumina or the like.

The bottom magnetic pole 16 forms a magnetic path together with the top magnetic pole 27 and is made of, for example, a magnetic material having high saturation magnetic flux density such as permalloy. The write gap layer 21 is a magnetic gap provided between the bottom magnetic pole 16 and the top magnetic pole 27 and is made of, for example, an insulating material such as alumina. The insulating layers 22 to 24 are provided to electrically isolate the thin film coils 25 and 26 from the periphery and are made of, for example, an insulating material such as photoresist or alumina. The thin film coils 25 and 26 generate magnetic flux and have a spiral structure made of a high conducting material such as copper (Cu). One end of the thin film coil 25 and one end of the thin film coil 26 are coupled to each other, and each of the other ends is provided with a pad for passing current. The top magnetic pole 27 receives magnetic flux generated by the thin film coils 25 and 26, thereby generating a magnetic field for writing near the write gap layer 21 through using the magnetic flux. The top magnetic pole 27 is made of a magnetic material having high saturation magnetic flux density such as permalloy or iron nitrogen (FeN). The top magnetic pole 27 is magnetically coupled to the bottom magnetic pole 16 via a back gap 21K formed in the write gap layer 21. On the top magnetic pole 27, further, an overcoat layer (not shown) for electrically isolating the write head core 102B from the periphery is provided.

In particularly, as shown in FIG. 9, the CPP-GMR element 30 in the read head core 102A is disposed between the bottom shield layer 12 and the top shield layer 14 serving as lead layers. The CPP-GMR element 30 has the MR layer pattern 31 disposed on the bottom shield layer 12 and a couple of gap layer patterns 32R and 32L and a couple of magnetic bias layer patterns 33R and 33L buried in spaces on both sides in the read track width direction (X axis direction) of the MR layer pattern 31. The “both sides in the read track width direction” are one side and the other side in the read track width direction (X axis direction), specifically, one side and the other side in the arrangement direction of the couple of gap layer patterns 32R and 32L and the couple of magnetic bias layer patterns 33R and 33L.

The MR layer pattern 31 corresponds to the first device layer pattern 2 (refer to FIG. 1). The MR layer pattern 31 has a stack structure (spin valve structure) including, for example, as shown in FIGS. 9 and 10, a pinning layer 312, a pinned layer 313, and a free layer 315. Concretely, the MR layer pattern 31 has a stack structure in which, for example, a seed layer 311, the pinning layer 312, the pinned layer 313, a spacer layer 314, the free layer 315, and a protection layer 316 are stacked in order from the side close to the bottom shield layer 12. The stack order from the pinning layer 312 to the free layer 315 may be, for example, the reverse.

The seed layer 311 is provided to stabilize the magnetic characteristic of a layer formed thereon (in this case, the pinning layer 312 and the like) and is made of a metal material such as nickel chromium alloy (NiCr). The pinning layer 312 pins the magnetization direction of the pinned layer 313 and is made of, for example, an antiferromagnetic material such as an iridium manganese alloy (IrMn). The magnetization direction of the pinned layer 313 is pinned by exchange coupling with the pinning layer 312, and the pinned layer 313 is made of materials including a ferromagnetic material such as cobalt iron alloy (CoFe). The pinned layer 313 may have, for example, a single-layer structure or a stack structure (so-called synthetic pinned layer) in which two ferromagnetic layers are stacked while having a nonmagnetic layer in between. The spacer layer 314 provides isolation between the pinned layer 313 and the free layer 315 and is made of, for example, a nonmagnetic material such as ruthenium (Ru). The magnetization direction of the free layer 315 is rotatable according to an external magnetic field, and the free layer 315 is made of materials including a ferromagnetic material such as a cobalt iron alloy. The free layer 315 may have, for example, a single-layer structure or a stack structure (so-called synthetic free layer) in which two ferromagnetic layers are stacked while having a nonmagnetic layer in between. The protection layer 316 protects a main part (mainly, a stack portion from the pinning layer 312 to the free layer 315) in the MR layer pattern 31 and is made of a nonmagnetic material such as tantalum (Ta).

The couple of gap layer patterns 32R and 32L correspond to part (lower layer) of the second device layer pattern 3 (refer to FIG. 1). As shown in FIG. 9, the gap layer patterns 32R and 32L have the function of electrically isolating the MR layer pattern 31 from the periphery and are disposed so as to be separated on both sides in the read track direction while having the MR layer pattern 31 in between. The gap layer patterns 32R and 32L are provided so as to cover the surface of the bottom shield layer 12 and the side faces of the MR layer pattern 31 and are made of, for example, an insulating material such as alumina or silicon oxide.

The couple of magnetic bias layer patterns 33R and 33L correspond to another part (upper layer) in the second device layer pattern 3 (refer to FIG. 1). The magnetic bias layer patterns 33R and 33L have the function of applying a magnetic bias to the MR layer pattern 31 and are disposed so as to be separated on both sides in the read track width direction while having the MR layer pattern 31 in between. The magnetic bias layer patterns 33R and 33L are provided on the gap layer patterns 32R and 32L, respectively, and are made of materials including a hard magnetic material such as a cobalt platinum alloy (CoPt) or cobalt platinum chromium alloy (CoPtCr). The magnetic bias layer patterns 33R and 33L may have, for example, a single-layer structure made of the hard magnetic material or a two-layer structure in which a nonmagnetic material layer (made of, for example, alumina, silicon oxide, tantalum, ruthenium, or the like) is provided on the hard magnetic material layer.

In the thin film magnetic head 102, at the time of reading information, a reading process is executed by the CPP-GMR element 30 in the read head core 102A. Specifically, in a state where sense current is supplied to the MR layer pattern 31 via the bottom shield layer 12 and the top shield layer 14 and the magnetic bias is applied from the magnetic bias layer patterns 33R and 33L to the MR layer pattern 31, through detecting a signal magnetic field of a recording medium, the magnetization direction of the free layer 315 rotates. Conduction electrons flowing in the MR layer pattern 31 meet with resistance according to the relative angle between the magnetization direction of the free layer 315 and the magnetization direction of the pinned layer 313. Since the resistance of the MR layer pattern 31 at this time changes according to the magnitude of the signal magnetic field (magnetoresistance effect), through detecting a resistance change in the MR layer pattern 31 as a voltage change, information recorded on the recording medium is magnetically read.

Next, by referring to FIGS. 6 to 14, a method of manufacturing the thin film magnetic head 102 shown in FIGS. 6 to 10 will be described. FIGS. 11 to 14 are used for explaining process of manufacturing the CPP-GMR element 30 and correspond to the sectional configuration shown in FIG. 9. In the following, first, manufacturing process for the thin film magnetic head 102 as a whole will be described by referring to FIGS. 6 to 8. After that, the process for manufacturing the CPP-GMR element 30 will be described in detail by referring to FIGS. 9 to 14. Since the materials of a series of components forming the thin film magnetic head 102 (including the CPP-GMR element 30) have been already described in detail, the description will not be repeated. The process of manufacturing the CPP-GMR element 30 will be described by properly referring to FIGS. 2 to 5 which have been referred to at the time of describing the method of forming the device structure.

The thin film magnetic head 102 can be manufactured through stacking a series of elements through using, for example, a method of forming a film typified by sputtering, electrolytic plating, or chemical vapor deposition (CVD), a patterning method typified by photolithography, an etching method typified by ion milling or RIE, and a polishing method typified by CMP. To be specific, the slider 101 is prepared. After that, the insulating layer 11, bottom shield layer 12, CPP-GMR element 30, insulating layer 13, and top shield layer 14 are stacked in this order on one of faces of the slider 101, thereby forming the read head core 102A. Subsequently, the nonmagnetic layer 15 is formed on the top shield layer 14 in the read head core 102A. After that, the bottom magnetic pole 16, write gap layer 21, thin film coils 25 and 26 buried by the insulating layers 22 to 24, and top magnetic pole 27 are stacked in this order on the nonmagnetic layer 15, thereby forming the write head core 102B. Finally, an overcoat layer (not shown) is formed so as to cover the write head core 102B and, after that, the stack structure including the read head core 102A and the write head core 102B is polished together with the slider 101, thereby forming the air bearing surface 101M, and the thin film magnetic head 102 is completed.

The CPP-GMR element 30 can be manufactured through applying the method of forming the device structure. Specifically, prior to manufacture of the GPP-GMR element 30, first, as shown in FIG. 11, the slider 101 is prepared. On the slider 101, the insulating layer 11 and the bottom shield layer 12 are stacked in order. The insulating layer 11 is formed through depositing an insulating material such as alumina or silicon oxide to a thickness of about 0.1 μm to 3 μm through using, for example, the sputtering, CVD, or the like. The bottom shield layer 12 is formed through depositing a magnetic material such as permalloy, iron cobalt nickel alloy, iron cobalt alloy, or the like to a thickness of about 0.1 μm to 3 μm through using, for example, sputtering, electrolytic plating, or the like.

At the time of forming the CPP-GMR element 30, first, as shown in FIG. 11, an MR layer 31Z corresponding to the first device layer 2Z (refer to FIG. 2) is formed on the bottom shield layer 12 (substrate). At the time of forming the MR layer 31Z, for example, as shown in FIG. 10, through using sputtering or the like, the seed layer 311, pinning layer 312, pinned layer 313, spacer layer 314, free layer 315, and protection layer 316 are stacked in this order on the bottom shield layer 12 so that each of the layers has a thickness of about 0.1 nm to 5 nm.

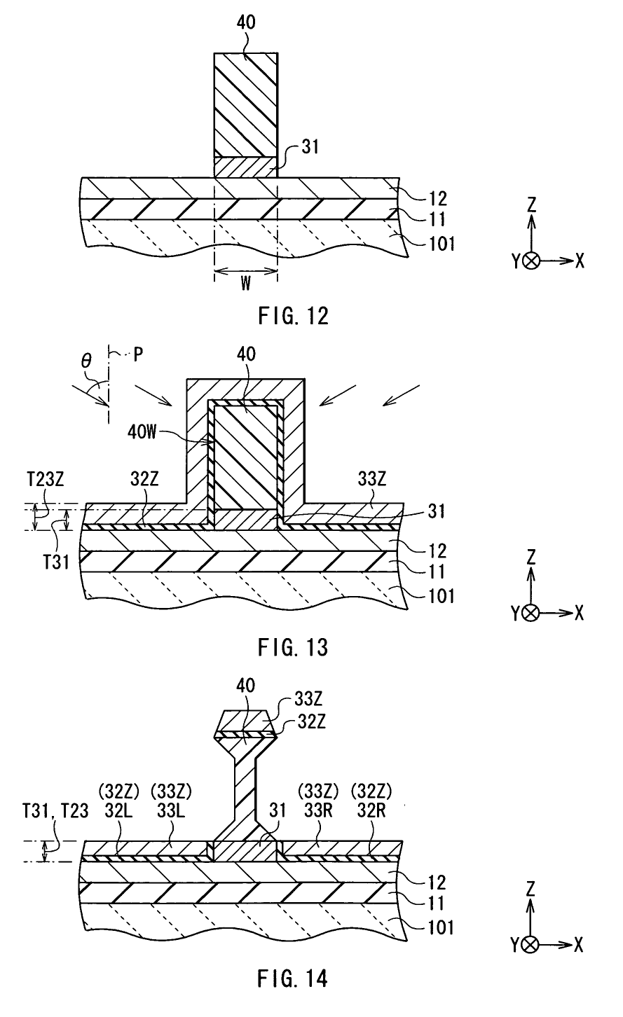

Subsequently, as shown in FIG. 11, a photoresist pattern 40 corresponding to the photoresist pattern 4 (refer to FIG. 2) is formed on the MR layer 31Z. The photoresist pattern 40 is formed through using a resist material such as poly-hydroxy-styrene (PHS) or novolak resin to a thickness of about 100 nm to 500 nm. In this case, in particular, the photoresist pattern 40 is formed so as to have a pattern shape (pattern width W=about 10 nm to 100 nm) corresponding to the pattern shape of the MR layer pattern 31 (refer to FIG. 12) to be formed in a post process. The resist structure of the photoresist pattern 40 may be, for example, as described above, a single-layer resist structure or a two-layer resist structure.

The photoresist patter 40 is used as a mask and selective etching (so-called patterning) is performed on the MR layer 31Z, thereby forming the MR layer pattern 31 corresponding to the first device layer pattern 2 (refer to FIG. 3) as shown in FIG. 12. At the time of forming the MR layer pattern 31, for example, etching such as ion milling or RIE is used. In this case, for example, the MR layer 31Z is etched and over-etched to the bottom shield layer 12. In other words, through adjusting the etching amount so that etching depth becomes larger than the thickness of the MR layer 31Z, etching may be performed into the bottom shield layer 12. Preferably, the etching depth in the bottom shield layer 12 is, for example, equal to about the thickness of a gap layer 32Z which will be described later.

As shown in FIG. 13, the gap layer 32Z and a magnetic bias layer 33Z (deposition layer) corresponding to the second device layer 3Z (refer to FIG. 4) are stacked in order so as to cover the MR layer pattern 31, the photoresist pattern 40, and the bottom shield layer 12 around them. The gap layer 32Z is formed through, for example, depositing an insulating material such as alumina or silicon oxide to a thickness of about 10 nm to 300 nm through using sputtering, CVD, or the like. The magnetic bias layer 33Z is formed through, for example, depositing a hard magnetic material such as a cobalt platinum alloy or cobalt platinum chromium alloy to a thickness of about 10 nm to 300 nm through using sputtering or the like. In this case, for example, total thickness T23Z of the gap layer 32Z and the magnetic bias layer 33Z is set to be larger than thickness T31 of the MR layer pattern 31 (T23Z>T31). In particular, at the time of forming the gap layer 32Z and the magnetic bias layer 33Z, the film formation range of the gap layer 32Z and the magnetic bias layer 33Z is set through using a photoresist pattern or the like so that the couple of gap layer patterns 32R and 32L and the couple of magnetic bias layer patterns 33R and 33L (refer to FIG. 14) can be disposed so as to be separated on both sides in the read track width direction of the MR layer pattern 31 in a post process. With the gap layer 32Z and the magnetic bias layer 33Z, a side wall 40W of the photoresist pattern 40 is covered.

Subsequently, as shown in FIG. 13, the gap layer 32Z and the magnetic bias layer 33Z covering the side wall 40W of the photoresist pattern 40 are selectively removed through oblique etching process. At the time of obliquely etching the gap layer 32Z and the magnetic bias layer 33Z, for example, ion milling is used and an ion beam (for example, argon ion (Ar⁺) or the like) is emitted from a direction at an angle θ of about 60° or more, preferably, about 60° to 80° from a perpendicular P of the bottom shield layer 12. For example, the gap layer 32Z and the magnetic bias layer 33Z covering the side wall 40W of the photoresist pattern 40 are over-etched.

Through the oblique etching process, as shown in FIG. 14, the couple of gap layer patterns 32R and 32L and the couple of magnetic bias layer patterns 33R and 33L (deposition layer patterns) corresponding to the second device layer pattern 3 (refer to FIG. 5) are stacked so as to bury the spaces on both sides in the read track width direction of the MR layer pattern 31, and the photoresist pattern 40 is partly narrowed near the center. Since the etching principle of oblique etching process has been described in detail, the description will not be repeated. In particular, at the time of obliquely etching the gap layer 32Z and the magnetic bias layer 33Z, for example, the etching amount is adjusted so that the total thickness T23 of the gap layer patterns 32R and 32L and the magnetic bias layer patterns 33R and 33L becomes equal to the thickness T31 of the MR layer pattern 31 (T23=T31).

Finally, the unnecessary gap layer 32Z and magnetic bias layer 33Z are removed together with the remaining photoresist pattern 40. The photoresist pattern 40 is removed through, for example, being immersed and rocked in an organic solvent or the like typified by acetone, isopropyl-alcohol (IPA), or N-methyl-2-pyrrolidone (NMP), or by ashing. The CPP-GMR element 30 is thereby completed.

In the method of manufacturing the thin film magnetic head, through applying the method of forming the device structure, the CPP-GMR element 30 is manufactured. Concretely, the MR layer 31Z is selectively etched through using the photoresist pattern 40 having the very small pattern width W, thereby forming the MR layer pattern 31. After that, the gap layer 32Z and the magnetic bias layer 33Z are formed so as to cover the MR layer pattern 31, the photoresist pattern 40, and the bottom shield layer 12 around them. Through selectively removing the gap layer 32Z and the magnetic bias layer 33Z covering the side wall 40W of the photoresist pattern 40 through oblique etching process, the couple of gap layer patterns 32R and 32L and the couple of magnetic bias layer patterns 33R and 33L are formed so as to be stacked. In this case, through an action similar to the method of forming the device structure, the MR layer pattern 31 is formed so as to have the very small pattern width W through using etching in place of using the lift off method, and the couple of gap layer patterns 32R and 32L and the couple of magnetic bias layer patterns 33R and 33L are stacked. Therefore, without using the lift off method, the invention can address the narrowing read track width.

In this case, in particular, through etching the gap layer 32Z and the magnetic bias layer 33Z so that the total thickness T23 of the gap layer patterns 32R and 32L and the magnetic bias layer patterns 33R and 33L becomes equal to the thickness T31 of the MR layer pattern 31 as described by referring to FIGS. 13 and 14, the surfaces of the MR layer pattern 31, gap layer patterns 32R and 32L, and magnetic bias layer patterns 33R and 33L in the completed CPP-GMR element 30 are planarized as shown in FIG. 9. Therefore, for the following reasons, the reading performance of the CPP-GMR element 30 can be assured.

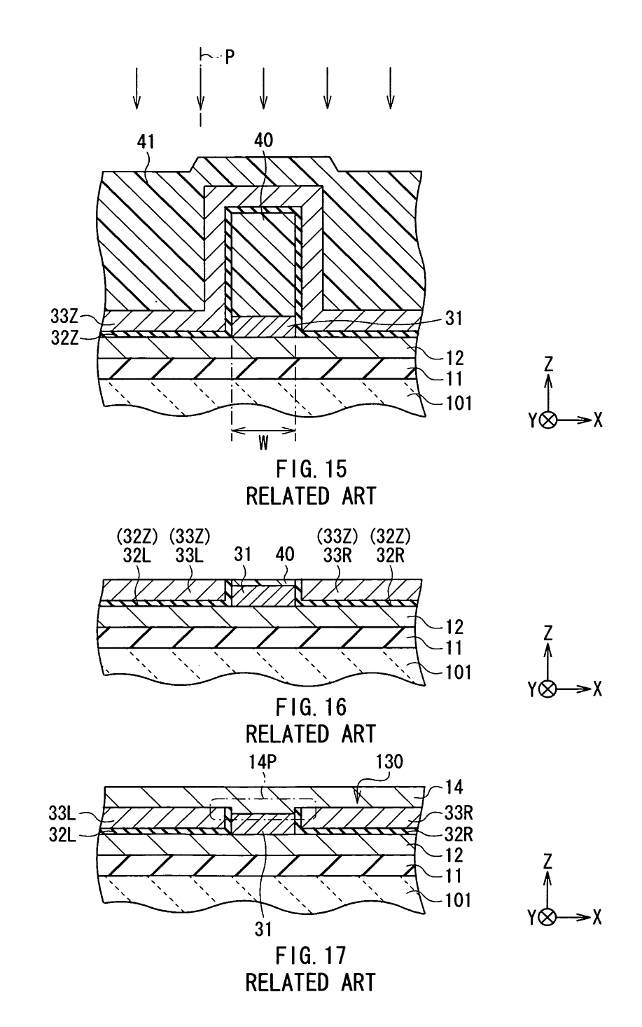

FIGS. 15 to 17 are diagrams for explaining a method of manufacturing a thin film magnetic head (a method of manufacturing a CPP-GMR element 130) as a comparative example of the method of manufacturing the thin film magnetic head of the present invention described by referring to FIGS. 11 to 14. FIGS. 15 to 17 correspond to the sectional configurations of FIGS. 11 to 14. In the method of manufacturing the thin film magnetic head of the comparative example, by the following manufacturing procedure, the CPP-GMR element 130 shown in FIG. 17 is manufactured. Specifically, first, by the manufacturing procedure described by referring to FIGS. 11 to 13, the layers are formed in order from the insulating layer 11 to the magnetic bias layer 33Z on the slider 101. After that, as shown in FIG. 15, a photoresist film 41 is formed so as to cover the magnetic bias layer 33Z. The photoresist film 41 is formed so that its surface becomes almost flat through completely covering the magnetic bias layer 33Z so that the whole can be flatly etched in a post process. Subsequently, as shown in FIG. 15, an etching action is performed from above the photoresist film 41 in parallel with the perpendicular P of the bottom shield layer 12 through using ion milling, thereby etching back the magnetic bias layer 33Z, gap layer 32Z, and photoresist pattern 40 together with the photoresist film 41. By the etch back, as shown in FIG. 16, the couple of gap layer patterns 32R and 32L and the couple of magnetic bias layer patterns 33R and 33L are formed. In particular, at the time of etching the gap layer 32Z and the magnetic bias layer 33Z, considering that the etching rate of the downward etching component is higher, the etching is finished so that the photoresist pattern 40 partly remains on the MR layer pattern 31 in order to prevent the MR layer pattern 31 from being unintentionally etched. Finally, the remaining photoresist pattern 40 is removed and the top shield layer 14 is formed as shown in FIG. 17, thereby completing the CPP-GMR element 130.

The CPP-GMR element 130 manufactured through using the method of manufacturing the thin film magnetic head of the comparative example has problems due to the manufacturing process from two viewpoints. First, as shown in FIGS. 15 and 16, in the process of etching the gap layer 32Z and the magnetic bias layer 33Z through using ion milling, since only the thin photoresist pattern 40 is provided on the MR layer pattern 31, an ion beam for etching easily transmits the photoresist pattern 40 and reaches the MR layer pattern 31. In this case, when the ion beam reaches the MR layer pattern 31, the MR layer pattern 31 suffers damage such as electrostatic destruction. Second, as shown in FIG. 16, when the etch back is performed so that the photoresist pattern 40 partly remains on the MR layer pattern 31, a dent (step) is created in a portion from which the photoresist pattern 40 is removed. Consequently, as shown in FIG. 17, when the top shield layer 14 is formed on the MR layer pattern 31, a downward projection 14P is provided in the top shield layer 14. In this case, when the CPP-GMR element 130 operates, the magnetic bias generated in the magnetic bias layer patterns 33R and 33L is inherently preferentially supplied to the MR layer pattern 31. However, part of the magnetic bias is supplied to the top shield layer 14 (the projection 14P) not to the MR layer pattern 31, so that an amount of the magnetic bias supplied from the magnetic bias layer patterns 33R and 33L to the MR layer pattern 31 substantially decreases. Due to the two problems, in the CPP-GMR element 130, it is difficult to assure the reading performance.

In contrast, in the CPP-GMR element 30 manufactured through using the method of manufacturing the thin film magnetic head of the present invention, as shown in FIGS. 13 and 14, the sufficiently thick photoresist pattern 40 is provided on the MR layer pattern 31 in the process of etching the gap layer 32Z and the magnetic bias layer 33Z through using ion milling. Therefore, an ion beam for etching does not easily pass through the photoresist pattern 40 and reach the MR layer pattern 31. It decreases the possibility that the MR layer pattern 31 suffers a damage such as electrostatic destruction. Moreover, as shown in FIG. 14, through performing the etching so that the total thickness T23 of the gap layer patterns 32R and 32L and the magnetic bias layer patterns 33R and 33L becomes equal to the thickness T31 of the MR layer pattern 31, the surfaces of the MR layer pattern 31, the gap layer patterns 32R and 32L, and the magnetic bias layer patterns 33R and 33L are planarized as shown in FIG. 9, so that no projection is created in the top shield layer 14. Consequently, in the operation of the CPP-GMR element 30, the magnetic bias generated in the magnetic bias layer patterns 33R and 33L is preferentially supplied to the MR layer pattern 31, so that the amount of the magnetic bias supplied from the magnetic bias layer patterns 33R and 33L to the MR layer pattern 31 is assured. Therefore, the CPP-GMR element 30 can assure the reading performance.

For confirmation, in the method of manufacturing the thin film magnetic head of the comparative example, when importance is placed on avoidance that the projection 14P is unintentionally provided in the top shield layer 14, it is possible to perform etching until the photoresist pattern 40 disappears. However, in this case, it is difficult to finish the etching in a desired position due to the high etching rate of the downward etching component as described above. Thus, the possibility that the MR layer pattern 31 is also unintentionally etched is extremely high. In contrast, in the method of manufacturing the thin film magnetic head of the present invention, through the oblique etching process, the etching rate of the lateral etching component is higher than that of the downward etching component. That is, the etching rate in the downward direction is relatively low, so that it is easy to finish the etching in a desired position. As a result, the progress of the etching can be easily controlled with high accuracy so that the total thickness T23 of the gap layer patterns 32R and 32L and the magnetic bias layer patterns 33R and 33L becomes equal to the thickness T31 of the MR layer pattern 31.

In the method of manufacturing the thin film magnetic head, the thin film magnetic head 102 is manufactured so as to have the CPP-GMR element 30. The invention, however, is not limited to the configuration. The kind of an MR element mounted on the thin film magnetic head 102 can be freely changed. In this case as well, effects similar to those of the method of manufacturing the thin film magnetic head can be obtained.

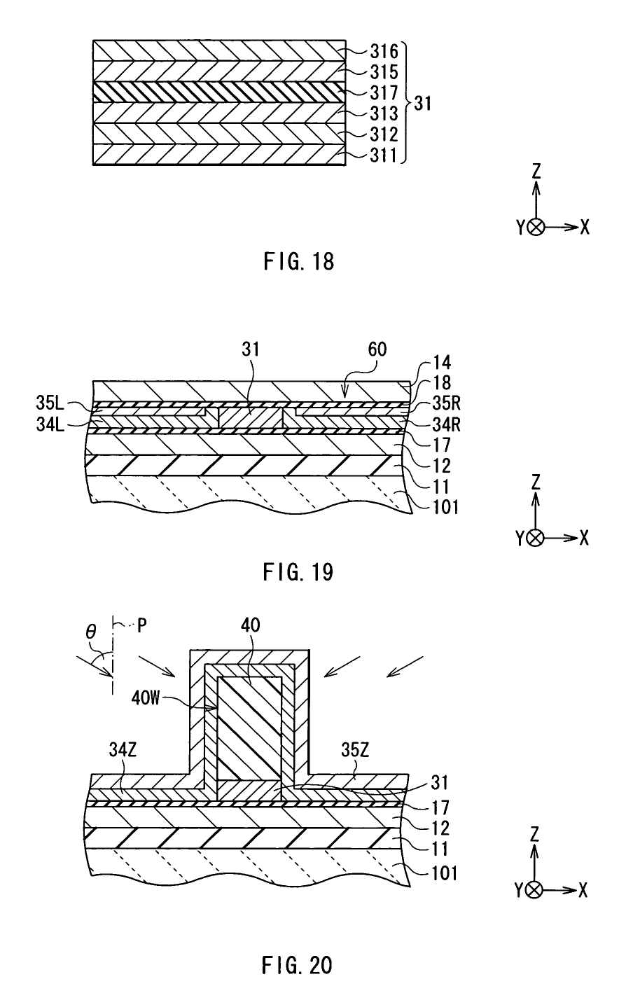

Concretely, first, for example, as shown in FIG. 9 and FIG. 18 corresponding to FIG. 10, an MTJ element 50 may be provided in place of the CPP-GMR element 30. The MTJ element 50 has, for example, as shown in FIG. 18, a configuration similar to that of the CPP-GMR element 30 except for the point that the MR layer pattern 31 includes a tunnel barrier layer 317 in place of the spacer layer 314. The tunnel barrier layer 317 is a layer through which electrons tunnel between the pinned layer 313 and the free layer 315 and is made of, for example, an insulating material such as alumina. In FIG. 9, since the CPP-GMR element 30 and the MTJ element 50 have configurations similar to each other except for the stack configuration of the MR layer pattern 31, the CPP-GMR element 30 and the MTJ element 50 are also shown.

Second, as shown in FIG. 10 and FIG. 19 corresponding to FIG. 9, a CIP-GMR element 60 may be provided in place of the CPP-GMR element 30. For example, as shown in FIG. 19, the CIP-GMR element 60 has a configuration similar to that of the CPP-GMR element 30 except for the points: (1) a couple of magnetic bias layer patterns 34R and 34L are provided in place of the couple of gap layer patterns 32R and 32L, (2) a couple of lead layer patterns 35R and 35L are provided in place of the couple of magnetic bias layer patterns 33R and 33L, (3) a bottom gap layer 17 is newly provided between the bottom shield layer 12 and the CIP-GMR element 60, and (4) a top gap layer 18 is newly provided between the top shield layer 14 and the CIP-GMR element 60. The magnetic bias layer patterns 34R and 34L have a function similar to that of the magnetic bias layer patterns 33R and 33L. The lead layer patterns 35R and 35L are used to supply sense current to the MR layer pattern 31 and are made of, for example, a conductive material such as gold (Au). The bottom gap layer 17 and the top gap layer 18 are provided to magnetically and electrically isolate the CIP-GMR element 60 from the periphery and are made of, for example, a nonmagnetic insulating material such as alumina or aluminum nitride (AlN). The CIP-GMR element 60 can be manufactured as follows. As shown in FIG. 20 corresponding to FIG. 13, mainly, a magnetic bias layer 34Z and a lead layer 35Z are formed in place of the gap layer 32Z and the magnetic bias layer 33Z, respectively. After that, through oblique etching process performed in a manner similar to that in the case described by referring to FIGS. 13 and 14, the couple of magnetic bias layer patterns 34R and 34L and the couple of lead layer patterns 35R and 35L are formed. The structure of this kind is generally called an “adjacent junction structure”.

In FIGS. 19 and 20, at the time of manufacturing the CIP-GMR element 60, the magnetic bias layer 34Z and the lead layer 35Z are stacked and obliquely etched, thereby forming the magnetic bias layer patterns 34R and 34L and the lead layer patterns 35R and 35L. However, the invention is not limited to the above. Concretely, it is also possible to form only the magnetic bias layer 34Z without forming the lead layer 35Z, obliquely etch the magnetic bias layer 34Z, thereby forming the magnetic bias layer patterns 34R and 34L and, after that, separately form the lead layer patterns 35R and 35L.

In the method of manufacturing the thin film magnetic head, a longitudinal write head is used as the write head core 102B in the thin film magnetic head 102. However, the invention is not always limited to a longitudinal write head. A perpendicular write head may be used as the write head core 102B. In this case as well, effects similar to those of the method of manufacturing the thin film magnetic head can be obtained.

Although the present invention has been described by the concrete embodiment, the invention is not limited to the embodiment but can be variously modified. Concretely, the a method of forming the device structure of the present invention can be freely changed as long as the pattern width can be narrowed without using the lift off method as follows. A first device layer is selectively etched through using a photoresist pattern, thereby forming a first device layer pattern. After that, a second device layer is formed so as to cover the first device layer pattern, the photoresist pattern, and a substrate around the first device layer pattern and the photoresist pattern, and the second device layer covering a side wall of the photoresist pattern is selectively removed through oblique etching process, thereby forming a second device layer pattern. Obviously, the method of manufacturing the magnetoresistive element or the method of manufacturing the thin film magnetic head of the invention can be also freely changed as long as it can address reduction in the read track width without using the lift-off method through manufacturing an MR element typified by a CPP-GMR element by applying the method of forming the device structure.

Although the case of applying the method of forming the device structure of the invention to a method manufacturing a thin film magnetic head (magnetoresistive element) has been described in the embodiment, the invention is not always limited to the case. The method of forming device structure can be applied to a method of manufacturing other devices than the thin film magnetic head. Examples of the “other devices” are laser diodes and various thin film sensors. Also in the case of applying the invention to the method of manufacturing the other devices, effects similar to those of the method of forming the device structure can be obtained.

The method of forming the device structure according to the invention can be applied to a method of manufacturing a device such as a thin film magnetic head (magnetoresistive element).

Obviously, many modifications and variations of the present invention are possible in the light of the above teachings. It is therefore to be understood that within the scope of the appended claims the invention may be practiced otherwise than as specifically described.

What is claimed is:

1. A method of forming a device structure comprising:
a first step of forming a first device layer so as to cover a substrate;
a second step of forming a photoresist pattern on the first device layer;
a third step of forming a first device layer pattern through selectively etching the first device layer using the photoresist pattern as a mask;
a fourth step of forming a second device layer so as to cover the first device layer pattern, the photoresist pattern, and the substrate around the first device layer pattern and the photoresist pattern;
a fifth step of selectively removing the second device layer covering a side wall of the photoresist pattern through oblique etching process, thereby forming a second device layer pattern so as to be filled in space around the first device layer pattern; and
a sixth step of removing the remaining photoresist pattern.

2. The method of forming the device structure according to claim 1, wherein in the fifth step, ion milling is performed, where an ion beam is emitted from a direction at an angle in the range from 60° to 80° from a perpendicular of the substrate.

3. The method of forming the device structure according to claim 1, wherein in the fifth step, the second device layer covering the side wall is over-etched.

4. The method of forming the device structure according to claim 1, wherein in the fourth step, the second device layer is formed so as to be thicker than the first device layer pattern, and
in the fifth step, the second device layer is etched so that the thickness of the second device layer pattern becomes equal to the thickness of the first device layer pattern.

5. A method of manufacturing a magnetoresistive element comprising:
a first step of forming a magnetoresistive layer so as to cover a substrate;
a second step of forming a photoresist pattern on the magnetoresistive layer;
a third step of forming a magnetoresistive layer pattern through selectively etching the magnetoresistive layer using the photoresist pattern as a mask;
a fourth step of forming a deposition layer so as to cover the magnetoresistive layer pattern, the photoresist pattern, and the substrate around the magnetoresistive layer pattern and the photoresist pattern;
a fifth step of selectively removing the deposition layer covering the side wall of the photoresist pattern through oblique etching process, thereby forming a deposition layer pattern so as to be filled in spaces on both sides in a read track width direction of the magnetoresistive layer pattern; and
a sixth step of removing the remaining photoresist pattern.

6. The method of manufacturing the magnetoresistive element according to claim 5, wherein in the fourth step, an insulating layer and a magnetic bias layer are stacked in this order as the deposition layer, thereby manufacturing a current-perpendicular-to-the-plane (CPP) giant magnetoresistive (GMR) element or a magnetic tunnel junction (MTJ) element.

7. The method of manufacturing the magnetoresistive element according to claim 5, wherein in the fourth step, a magnetic bias layer and a lead layer are stacked in this order as the deposition layer, thereby manufacturing a current-in-the-plane (CIP) giant magnetoresistive (GMR) element.

8. The method of manufacturing the magnetoresistive element according to claim 5, wherein in the first step, the magnetoresistive layer is formed so as to have a stack structure including a pinning layer, a pinned layer, and a free layer.

9. A method of manufacturing a thin film magnetic head having a magnetoresistive element, wherein the magnetoresistive element is manufactured through using the method of manufacturing the magnetoresistive element according to claim 5.
